(19) United States
(12) Patent Application Publication
(10) Pub. No.: US 2018/0048335 A1
(43) Pub. Date: Feb. 15, 2018

(54) METHODS AND APPARATUS FOR DECODER PROCESSING FOR JOINT MULTI-USER DETECTION

(71) Applicant: QUALCOMM Incorporated, San Diego, CA (US)

(72) Inventors: Haitong Sun, San Diego, CA (US); Tingfang Ji, San Diego, CA (US)

(21) Appl. No.: 15/499,514

(22) Filed: Apr. 27, 2017

Related U.S. Application Data
(60) Provisional application No. 62/373,849, filed on Aug. 11, 2016.

(51) Int. Cl. H03M 13/45; H04L 1/00; H03M 13/29

(52) U.S. Cl. CPC H03M 13/45; H03M 13/2957; H04L 1/0045; H04L 1/0057

(57) ABSTRACT

Methods and apparatus are described for decoder processing. The methods and apparatus determine decoding performance occurring in a decoder having first and second decoder components with a feedback component between the first and second decoder components. The feedback is selectively switching between feedback passing soft information between the first and second decoder components and feedback passing hard information between the first and second decoder components based on the determined decoding performance.

### CLAIM OF BENEFIT UNDER 35 U.S.C. § 119

The present Application for Patent claims the benefit of U.S. Provisional Application No. 62/373,849 entitled “METHODS AND APPARATUS FOR TURBO PROCESSING FOR JOINT MULTI-USER DETECTION” filed Aug. 11, 2016, assigned to the assignee hereof and hereby expressly incorporated by reference herein.

### TECHNICAL FIELD

The present application relates generally to wireless communication systems, and more particularly, to methods and apparatus for decoder processing for joint multi-user detection in non-orthogonal multiple access systems.

### INTRODUCTION

Non-orthogonal multiple access schemes, such as Sparse Code Multiple Access (SCMA), have been proposed for fifth generation (5G) communication standards. SCMA utilizes a non-orthogonal waveform that engenders a multiple access scheme. Particularly with non-orthogonal multiple access systems, multi-user detection is important for achieving more efficient communication.

A typical digital transmit chain consists of multiple components such as channel encoding, modulation mapping, layer mapping, and precoding, as examples. For such chains, a known receiver that jointly process all of the transmit component blocks is a maximum a posteriori probability/maximum likelihood (MAP/ML) receiver. Although the performance of such MAP/ML receivers is considered optimum, the complexity of these receivers make them unfeasible for a number of different applications, such as in mobile devices. Thus, it is also known to utilize Turbo processing, which provides an iterative soft information exchange between decoders for each of the transmit component blocks, and can approach the receiver performance of MAP/ML receivers, for example, with greatly reduced complexity. In Turbo processing, however, reduction or degradation of the decoding performance can arise due to extrinsic information exchange (i.e., iterative soft information feedback) needed for such processing. For example, low-density parity-check (LDPC) and Message Passing Algorithm (MPA) decoders can saturate, which then prevents extrinsic feedback information from being updated correctly, thus presenting numerical problems. The performance deterioration could also be due to error propagation or algorithm issues as well. Accordingly, there exists a need for improved processing, such as Turbo processing, which improves the degraded or reduced decoding performance that may arise during decoding.

### SUMMARY

According to an aspect of the present disclosure, a method of wireless communication is disclosed. The method includes determining decoding performance occurring in a decoder having first and second decoder components with a feedback component between the first and second decoder components. Further, the method includes selectively switching between feedback passing soft information between the first and second decoder components with the feedback component and feedback passing hard information between the first and second decoder components based on the determined decoding performance.

In another aspect, an apparatus for wireless communication is disclosed. The apparatus includes at least one processor, a transceiver communicatively coupled to the at least one processor and including at least one decoder, and a memory communicatively coupled to the at least one processor. The at least one processor is configured to determine decoding performance occurring in the decoder that includes first and second decoder components and a feedback component between the first and second decoder components. Further, the at least one processor is configured to selectively switch between feedback passing soft information between the first and second decoder components with the feedback component and feedback passing hard information between the first and second decoder components based on the determined decoding performance

In yet another aspect, a non-transitory computer-readable medium storing computer-executable code is disclosed, the medium comprising code for causing a computer to determine decoding performance occurring in a decoder having first and second decoder components with a feedback component between the first and second decoder components. The medium further include code for causing a computer to selectively switch between feedback passing soft information between the first and second decoder components with the feedback component and feedback passing hard information between the first and second decoder components based on the determined decoding performance

### BRIEF DESCRIPTION OF THE DRAWINGS

FIG. 1 is a conceptual diagram illustrating an example of an access network.

FIG. 2 is a block diagram conceptually illustrating an example of a scheduling entity communicating with one or more scheduled entities according to some embodiments.

FIG. 3 illustrates a plot of a known example of an SCMA codebook constellation.

FIG. 4 illustrates a block diagram of a modeled transmitter and receiver system that may employ the disclosed hybrid or modified Turbo decoding methods and apparatus.

FIG. 5 illustrates a block diagram of an exemplary Turbo decoder scheme.

FIG. 6 illustrates a block diagram of an exemplary Turbo decoder scheme with modified structure and/or operation in accordance with the present disclosure.

FIG. 7 illustrates plots of the block error rate (BLER) with respect to the symbol signal to noise ratio (SNR) per bit (i.e., Es/No (Energy per Symbol divided by noise power spectral density)) for a conventional Turbo decoder of the system and the presently disclosed modified decoder of FIG. 6.

FIG. 8 is a block diagram illustrating an example of a hardware implementation for an apparatus employing a processing system.

FIG. 9 is a flow diagram of an exemplary method for decoding using a modified or hybrid decoding scheme.

### DETAILED DESCRIPTION

The detailed description set forth below in connection with the drawings is intended as a description of various configurations and is not intended to represent the only configurations in which the concepts described herein may be practiced. The detailed description includes specific details for the purpose of providing a thorough understanding of various concepts. It will be apparent to those skilled in the art, however, that these concepts may be practiced without these specific details. In some instances, well-known structures and components are shown in block diagram form in order to avoid obscuring such concepts.

The presently disclosed methods and apparatus provide a modified or hybrid Turbo processing scheme to mitigate numerical issues and thereby improve processing performance of such Turbo processing. In particular, the present disclosure provides for dynamic identification or detection of occurrences of a numerical problem through at least the tracking of the packet decoding success rate. When the occurrence of a numerical problem is detected, the present disclosure provides for selective switching between hard and soft information exchange or feedback (e.g., switching between Turbo soft information and low-density parity-check (LDPC) hard information). In one aspect, if the feedback information is switched from Turbo soft information to LDPC hard information upon the detection of a numerical problem to terminate turbo processing early. In this manner, the performance deterioration is curtailed and the performance of the decoding process is ameliorated, accordingly.

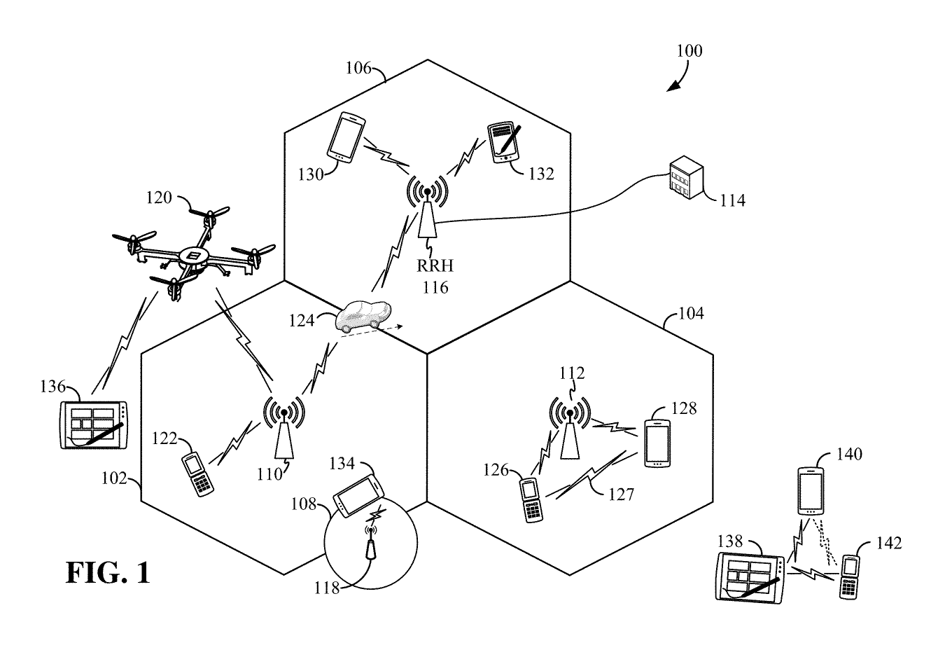

The various concepts presented throughout this disclosure may be implemented across a broad variety of telecommunication systems, network architectures, and communication standards. Referring to FIG. 1, as an illustrative example without limitation, a simplified schematic illustration of an access network 100 is provided.

The geographic region covered by the access network 100 may be divided into a number of cellular regions (cells), including macrocells 102, 104, and 106, and a small cell 108, each of which may include one or more sectors. Cells may be defined geographically (e.g., by coverage area) and/or may be defined in accordance with a frequency, scrambling code, etc. In a cell that is divided into sectors, the multiple sectors within a cell can be formed by groups of antennas with each antenna responsible for communication with mobile devices in a portion of the cell.

In general, a radio transceiver apparatus serves each cell. A radio transceiver apparatus is commonly referred to as a base station (BS) in many wireless communication systems, but may also be referred to by those skilled in the art as a base transceiver station (BTS), a radio base station, a radio transceiver, a transceiver function, a basic service set (BSS), an extended service set (ESS), an access point (AP), a Node B, an eNode B, gNB, or some other suitable terminology.

In FIG. 1, two high-power base stations 110 and 112 are shown in cells 102 and 104; and a third high-power base station 114 is shown controlling a remote radio head (RRH) 116 in cell 106. That is, a base station can have an integrated antenna or can be connected to an antenna or RRH by feeder cables. In the illustrated example, the cells 102, 104, and 106 may be referred to as macrocells, as the high-power base stations 110, 112, and 114 support cells having a large size. Further, a low-power base station 118 is shown in the small cell 108 (e.g., a microcell, picocell, femtocell, home base station, home Node B, home eNode B, gNB, etc.) which may overlap with one or more macrocells. In this example, the cell 108 may be referred to as a small cell, as the low-power base station 118 supports a cell having a relatively small size. Cell sizing can be done according to system design as well as component constraints. It is to be understood that the radio access network 100 may include any number of wireless base stations and cells. Further, a relay node may be deployed to extend the size or coverage area of a given cell. The base stations 110, 112, 114, 118 provide wireless access points to a core network for any number of mobile apparatuses.

FIG. 1 further includes a mobile or airborne node 120 such as a quadcopter or drone that may be configured to function as a base station. That is, in some examples, a cell may not necessarily be stationary, and the geographic area of the cell may move according to the location of a mobile base station such as the quadcopter 120.

In general, base stations may include a backhaul interface for communication with a backhaul portion of the network. The backhaul may provide a link between a base station and a core network, and in some examples, the backhaul may provide interconnection between the respective base stations. The core network is a part of a wireless communication system that is generally independent of the radio access technology used in the radio access network. Various types of backhaul interfaces may be employed, such as a direct physical connection, a virtual network, or the like using any suitable transport network. Some base stations may be configured as integrated access and backhaul (IAB) nodes, where the wireless spectrum may be used both for access links (i.e., wireless links with UEs), and for backhaul links. This scheme is sometimes referred to as wireless self-backhauling. By using wireless self-backhauling, rather than requiring each new base station deployment to be outfitted with its own hard-wired backhaul connection, the wireless spectrum utilized for communication between the base station and UE may be leveraged for backhaul communication, enabling fast and easy deployment of highly dense small cell networks.

The radio access network 100 is illustrated supporting wireless communication for multiple mobile apparatuses. A mobile apparatus is commonly referred to as user equipment (UE) in standards and specifications promulgated by the 3rd Generation Partnership Project (3GPP), but may also be referred to by those skilled in the art as a mobile station (MS), a subscriber station, a mobile unit, a subscriber unit, a wireless unit, a remote unit, a mobile device, a wireless device, a wireless communications device, a remote device, a mobile subscriber station, an access terminal (AT), a mobile terminal, a wireless terminal, a remote terminal, a handset, a terminal, a user agent, a mobile client, a client, or some other suitable terminology. A UE may be an apparatus that provides a user with access to network services.

Within the present document, a “mobile” apparatus need not necessarily have a capability to move, and may be stationary. The term mobile apparatus or mobile device broadly refers to a diverse array of devices and technologies. For example, some non-limiting examples of a mobile apparatus include a mobile, a cellular (cell) phone, a smart phone, a session initiation protocol (SIP) phone, a laptop, a personal computer (PC), a notebook, a netbook, a smartbook, a tablet, a personal digital assistant (PDA), and a broad array of embedded systems, e.g., corresponding to an “Internet of things” (IoT). A mobile apparatus may additionally be an automotive or other transportation vehicle, a remote sensor or actuator, a robot or robotics device, a satellite radio, a global positioning system (GPS) device, an object tracking device, a drone, a multi-copter, a quad-copter, a remote control device, a consumer and/or wearable device, such as eyewear, a wearable camera, a virtual reality device, a smart watch, a health or fitness tracker, a digital audio player (e.g., MP3 player), a camera, a game console, etc. A mobile apparatus may additionally be a digital home or smart home device such as a home audio, video, and/or multimedia device, an appliance, a vending machine, intelligent lighting, a home security system, a smart meter, etc. A mobile apparatus may additionally be a smart energy device, a security device, a solar panel or solar array, a municipal infrastructure device controlling electric power (e.g., a smart grid), lighting, water, etc.; an industrial automation and enterprise device; a logistics controller; agricultural equipment; military defense equipment, vehicles, aircraft, ships, and weaponry, etc. Still further, a mobile apparatus may provide for connected medicine or telemedicine support, i.e., health care at a distance. Telehealth devices may include telehealth monitoring devices and telehealth administration devices, whose communication may be given preferential treatment or prioritized access over other types of information, e.g., in terms of prioritized access for transport of critical service data, and/or relevant QoS for transport of critical service data.

Within the radio access network 100, the cells may include UEs that may be in communication with one or more sectors of each cell. For example, UEs 122 and 124 may be in communication with base station 110; UEs 126 and 128 may be in communication with base station 112; UEs 130 and 132 may be in communication with base station 114 by way of RRH 116; UE 134 may be in communication with low-power base station 118; and UE 136 may be in communication with mobile base station 120. Here, each base station 110, 112, 114, 118, and 120 may be configured to provide an access point to a core network (not shown) for all the UEs in the respective cells.

In another example, a mobile network node (e.g., quadcopter 120) may be configured to function as a UE. For example, the quadcopter 120 may operate within cell 102 by communicating with base station 110. In some aspects of the disclosure, two or more UE (e.g., UEs 126 and 128) may communicate with each other using peer to peer (P2P) or sidelink signals 127 without relaying that communication through a base station (e.g., base station 112).

Unicast or broadcast transmissions of control information and/or traffic information from a base station (e.g., base station 110) to one or more UEs (e.g., UEs 122 and 124) may be referred to as downlink (DL) transmission, while transmissions of control information and/or traffic information originating at a UE (e.g., UE 122) may be referred to as uplink (UL) transmissions. In addition, the uplink and/or downlink control information and/or traffic information may be time-divided into frames, subframes, slots, and/or symbols. As used herein, a symbol may refer to a unit of time that, in an OFDM waveform, carries one resource element (RE) per subcarrier. A slot may carry 7 or 14 OFDM symbols in a couple of examples. A subframe may refer to a duration of 1 ms. Multiple subframes may be grouped together to form a single frame or radio frame. Of course, these definitions are not required, and any suitable scheme for organizing waveforms may be utilized, and various time divisions of the waveform may have any suitable duration.

The air interface in the radio access network 100 may utilize one or more multiplexing and multiple access algorithms to enable simultaneous communication of the various devices. For example, multiple access for uplink (UL) or reverse link transmissions from UEs 122 and 124 to base station 110 may be provided utilizing time division multiple access (TDMA), code division multiple access (CDMA), frequency division multiple access (FDMA), orthogonal frequency division multiple access (OFDMA), sparse code multiple access (SCMA), resource spread multiple access (RSMA), or other suitable multiple access schemes. Further, multiplexing downlink (DL) or forward link transmissions from the base station 110 to UEs 122 and 124 may be provided utilizing time division multiplexing (TDM), code division multiplexing (CDM), frequency division multiplexing (FDM), orthogonal frequency division multiplexing (OFDM), sparse code multiplexing (SCM), or other suitable multiplexing schemes.

Additionally, the air interface in the radio access network 100 may utilize one or more duplexing algorithms Duplex refers to a point-to-point communication link where both endpoints can communicate with one another in both directions. Full duplex means both endpoints can simultaneously communicate with one another. Half duplex means only one endpoint can send information to the other at a time. In a wireless link, a full duplex channel generally relies on physical isolation of a transmitter and receiver, and suitable interference cancellation technologies. Full duplex emulation is frequently implemented for wireless links by utilizing frequency division duplex (FDD) or time division duplex (TDD). In FDD, transmissions in different directions operate at different carrier frequencies. In TDD, transmissions in different directions on a given channel are separated from one another using time division multiplexing. That is, at some times the channel is dedicated for transmissions in one direction, while at other times the channel is dedicated for transmissions in the other direction, where the direction may change very rapidly, e.g., several times per slot.

In the radio access network 100, the ability for a UE to communicate while moving, independent of its location, is referred to as mobility. The various physical channels between the UE and the radio access network are generally set up, maintained, and released under the control of a mobility management entity (MME). In various aspects of the disclosure, a radio access network 100 may utilize DL-based mobility or UL-based mobility to enable mobility and handovers (i.e., the transfer of a UE's connection from one radio channel to another). In a network configured for DL-based mobility, during a call with a scheduling entity, or at any other time, a UE may monitor various parameters of the signal from its serving cell as well as various parameters of neighboring cells. Depending on the quality of these parameters, the UE may maintain communication with one or more of the neighboring cells. During this time, if the UE moves from one cell to another, or if signal quality from a neighboring cell exceeds that from the serving cell for a given amount of time, the UE may undertake a handoff or handover from the serving cell to the neighboring (target) cell. For example, UE 124 (illustrated as a vehicle, although any suitable form of UE may be used) may move from the geographic area corresponding to its serving cell 102 to the geographic area corresponding to a neighbor cell 106. When the signal strength or quality from the neighbor cell 106 exceeds that of its serving cell 102 for a given amount of time, the UE 124 may transmit a reporting message to its serving base station 110 indicating this condition. In response, the UE 124 may receive a handover command, and the UE may undergo a handover to the cell 106.

In a network configured for UL-based mobility, UL reference signals from each UE may be utilized by the network to select a serving cell for each UE. In some examples, the base stations 110, 112, and 114/116 may broadcast unified synchronization signals (e.g., unified Primary Synchronization Signals (PSSs), unified Secondary Synchronization Signals (SSSs) and unified Physical Broadcast Channels (PBCH)). The UEs 122, 124, 126, 128, 130, and 132 may receive the unified synchronization signals, derive the carrier frequency and slot timing from the synchronization signals, and in response to deriving timing, transmit an uplink pilot or reference signal. The uplink pilot signal transmitted by a UE (e.g., UE 124) may be concurrently received by two or more cells (e.g., base stations 110 and 114/116) within the radio access network 100. Each of the cells may measure a strength of the pilot signal, and the radio access network (e.g., one or more of the base stations 110 and 114/116 and/or a central node within the core network) may determine a serving cell for the UE 124. As the UE 124 moves through the radio access network 100, the network may continue to monitor the uplink pilot signal transmitted by the UE 124. When the signal strength or quality of the pilot signal measured by a neighboring cell exceeds that of the signal strength or quality measured by the serving cell, the network 100 may handover the UE 124 from the serving cell to the neighboring cell, with or without informing the UE 124.

Although the synchronization signal transmitted by the base stations 110, 112, and 114/116 may be unified, the synchronization signal may not identify a particular cell, but rather may identify a zone of multiple cells operating on the same frequency and/or with the same timing. The use of zones in 5G networks or other next generation communication networks enables the uplink-based mobility framework and improves the efficiency of both the UE and the network, since the number of mobility messages that need to be exchanged between the UE and the network may be reduced.

In various implementations, the air interface in the radio access network 100 may utilize licensed spectrum, unlicensed spectrum, or shared spectrum. Licensed spectrum provides for exclusive use of a portion of the spectrum, generally by virtue of a mobile network operator purchasing a license from a government regulatory body. Unlicensed spectrum provides for shared use of a portion of the spectrum without need for a government-granted license. While compliance with some technical rules is generally still required to access unlicensed spectrum, generally, any operator or device may gain access. Shared spectrum may fall between licensed and unlicensed spectrum, wherein technical rules or limitations may be required to access the spectrum, but the spectrum may still be shared by multiple operators and/or multiple RATs. For example, the holder of a license for a portion of licensed spectrum may provide licensed shared access (LSA) to share that spectrum with other parties, e.g., with suitable licensee-determined conditions to gain access.

In some examples, access to the air interface may be scheduled, wherein a scheduling entity (e.g., a base station) allocates resources for communication among some or all devices and equipment within its service area or cell. Within the present disclosure, as discussed further below, the scheduling entity may be responsible for scheduling, assigning, reconfiguring, and releasing resources for one or more scheduled entities. That is, for scheduled communication, UEs or scheduled entities utilize resources allocated by the scheduling entity.

Base stations are not the only entities that may function as a scheduling entity. That is, in some examples, a UE may function as a scheduling entity, scheduling resources for one or more scheduled entities (e.g., one or more other UEs). In other examples, sidelink signals may be used between UEs without necessarily relying on scheduling or control information from a base station. For example, UE 138 is illustrated communicating with UEs 140 and 142. In some examples, the UE 138 is functioning as a scheduling entity or a primary sidelink device, and UEs 140 and 142 may function as a scheduled entity or a non-primary (e.g., secondary) sidelink device. In still another example, a UE may function as a scheduling entity in a device-to-device (D2D), peer-to-peer (P2P), or vehicle-to-vehicle (V2V) network, and/or in a mesh network. In a mesh network example, UEs 140 and 142 may optionally communicate directly with one another in addition to communicating with the scheduling entity 138.

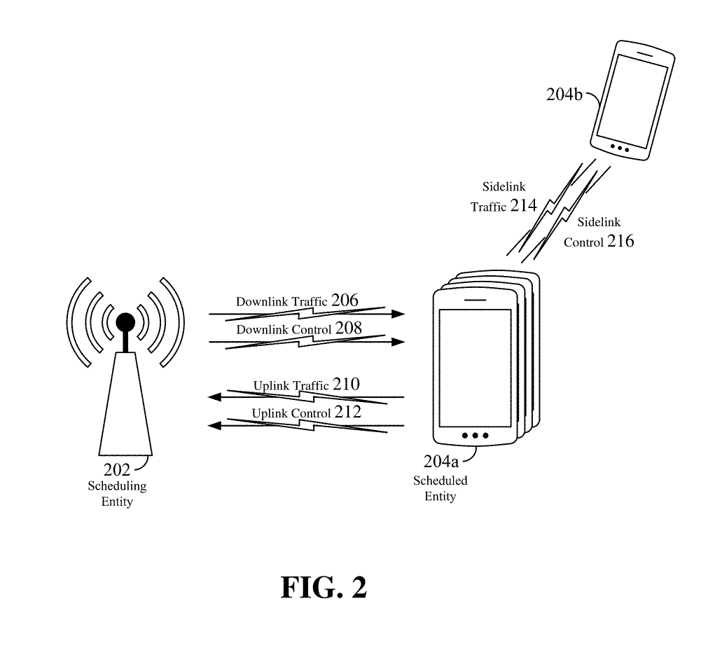

Thus, in a wireless communication network with scheduled access to time—frequency resources and having a cellular configuration, a P2P configuration, or a mesh configuration, a scheduling entity and one or more scheduled entities may communicate utilizing the scheduled resources. Referring now to FIG. 2, a block diagram illustrates a scheduling entity 202 and a plurality of scheduled entities 204 (e.g., 204a and 204b). Here, the scheduling entity 202 may correspond to a base station 110, 112, 114, and/or 118. In additional examples, the scheduling entity 202 may correspond to a UE 138, the quadcopter 120, or any other suitable node in the radio access network 100. Similarly, in various examples, the scheduled entity 204 may correspond to the UE 122, 124, 126, 128, 130, 132, 134, 136, 138, 140, and 142, or any other suitable node in the radio access network 100.

As illustrated in FIG. 2, the scheduling entity 202 may broadcast traffic 206 to one or more scheduled entities 204 (the traffic may be referred to as downlink (DL) traffic). In accordance with certain aspects of the present disclosure, the term downlink may refer to a point-to-multipoint transmission originating at the scheduling entity 202. Broadly, the scheduling entity 202 is a node or device responsible for scheduling traffic in a wireless communication network, including the downlink transmissions and, in some examples, uplink traffic 210 from one or more scheduled entities to the scheduling entity 202. Another way to describe the system may be to use the term broadcast channel multiplexing. In accordance with aspects of the present disclosure, the term uplink may refer to a point-to-point transmission originating at a scheduled entity 204. Broadly, the scheduled entity 204 is a node or device that receives scheduling control information, including but not limited to scheduling grants, synchronization or timing information, or other control information from another entity in the wireless communication network such as the scheduling entity 202.

The scheduling entity 202 may broadcast control information 208 including one or more control channels, such as a PBCH, a PSS, an SSS, a physical control format indicator channel (PCFICH), a physical hybrid automatic repeat request (HARQ) indicator channel (PHICH), and/or a physical downlink control channel (PDCCH), etc., to one or more scheduled entities 204. The PHICH carries HARQ feedback transmissions such as an acknowledgment (ACK) or negative acknowledgment (NACK). HARQ is a technique well known to those of ordinary skill in the art, wherein packet transmissions may be checked at the receiving side for accuracy, and if confirmed, an ACK may be transmitted, whereas if not confirmed, a NACK may be transmitted. In response to a NACK, the transmitting device may send a HARQ retransmission, which may implement chase combining, incremental redundancy, etc.

Uplink traffic 210 and/or downlink traffic 206 including one or more traffic channels, such as a physical downlink shared channel (PDSCH) or a physical uplink shared channel (PUSCH) (and, in some examples, system information blocks (SIBs)), may additionally be transmitted between the scheduling entity 202 and the scheduled entity 204. Transmissions of the control and traffic information may be organized by subdividing a carrier, in time, into suitable time intervals (e.g., transmission time intervals (TTIs) or similar constructs).

Furthermore, the scheduled entities 204 may transmit uplink control information 212 including one or more uplink control channels to the scheduling entity 202. Uplink control information may include a variety of packet types and categories, including pilots, reference signals, and information configured to enable or assist in decoding uplink traffic transmissions. In some examples, the control information 212 may include a scheduling request (SR), i.e., request for the scheduling entity 202 to schedule uplink transmissions. Here, in response to the SR transmitted on the control channel 212, the scheduling entity 202 may transmit downlink control information 208 that may schedule the TTI for uplink packet transmissions.

Uplink and downlink transmissions may generally utilize a suitable error correcting block code. In a typical block code, an information message or sequence is split up into blocks, and an encoder at the transmitting device then mathematically adds redundancy to the information message. Exploitation of this redundancy in the encoded information message can improve the reliability of the message, enabling correction for any bit errors that may occur due to the noise. Some examples of error correcting codes include Hamming codes, Bose-Chaudhuri-Hocquenghem (BCH) codes, turbo codes, low-density parity check (LDPC) codes, and polar codes. Various implementations of scheduling entities 202 and scheduled entities 204 may include suitable hardware and capabilities (e.g., an encoder and/or a decoder) to utilize any one or more of these error correcting codes for wireless communication.

In some examples, scheduled entities such as a first scheduled entity 204a and a second scheduled entity 204b may utilize sidelink signals for direct D2D communication. Sidelink signals may include sidelink traffic 214 and sidelink control 216. Sidelink control information 216 may include a request-to-send (RTS) channel and a clear-to-send (CTS) channel. The RTS may provide for a scheduled entity 204 to request a duration of time to keep a sidelink channel available for a sidelink signal; and the CTS may provide for the scheduled entity 204 to indicate the availability of the sidelink channel, e.g., for a requested duration of time. An exchange of RTS and CTS signals (e.g., handshake) may enable different scheduled entities performing sidelink communications to negotiate the availability of the sidelink channel prior to communication of the sidelink traffic information 214.

The channels illustrated in FIG. 2 are not necessarily all of the channels that may be utilized between a scheduling entity 202 and scheduled entities 204, and those of ordinary skill in the art will recognize that other channels or carriers may be utilized in addition to those illustrated, such as other traffic, data, control, and feedback channels. It is noted that the transmission schemes utilized by the scheduling entity 202 and the scheduled entities 204 may include sparse code multiple access (SCMA), time division multiple access (TDMA), code division multiple access (CDMA), frequency division multiple access (FDMA), orthogonal frequency division multiple access (OFDMA), or other suitable multiple access schemes.

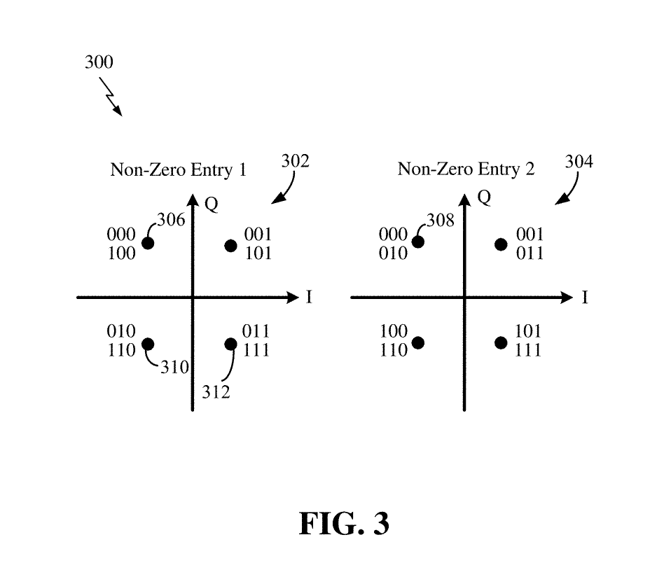

With regard to SCMA schemes proposed for 5G communications, in particular, when transmitting signals a transceiver in a communication device, whether in a scheduling entity 202 or a scheduled entity 204 as examples, employs an SCMA codebook that allows encoded bits to be mapped to a codeword for SCMA transmission (or demapped in the case of the receiver side). In an example of a known 3-bit codebook mapping scheme, FIG. 3 illustrates an exemplary 8 point codebook 300 (or multi-dimensional constellation) on two non-zero entries. As may be seen, the first non-zero entry constellation 302 includes four (4) constellation points each representing one of two 3 bit values for representing numbers zero through 7 in binary (i.e., 000 through 111). Similarly, the second non-zero entry constellation 304 also includes four (4) constellation points each representing one of two 3 bit values for also representing numbers zero through 7 in binary (i.e., 000 through 111). As may be further seen in FIG. 3 the different first and second entries have respective constellations that share the same representation of one of the bit values, but have a different bit value for the second value. For example, the bit value for the constellation point 306 in the upper left quadrant of constellation 302 may represent bit values “000” and “100”, whereas the constellation point 308 in the upper left quadrant of constellation 304 may represent bit values “000” and “010.”

Still further, the constellation points within a non-zero entity may be Gray coded where only one bit change occurs between points in the constellation. For example, only one bit change occurs in the values from point 306 to point 310 (i.e., 000 to 010 or 100 to 110), or from point 310 to point 312 (i.e., 010 to 011 or 110 to 111). In another example that is not illustrated in FIG. 3, the constellation points from one layer may be Gray coded with respect to constellation points in another layer.

It is noted that for UEs, in particular, each UE may choose an SCMA codebook on their own. When there are multiple UEs that are active at the same time, codebook collisions may occur if one or more of the multiple UEs transmit with the same codebook. In the example above and assuming six active UEs (e.g., UE1 through UE6), it is noted that no collisions would occur between the UEs with the particular signature matrix S being used by all of the UEs. If the UEs choose the codebook on their own, however, collisions may occur. For example, UE1 and UE2 may choose a first codebook from the matrix above, UE3 and UE4 choose a third codebook from the matrix above, and UE5 and UE6 choose a fifth codebook from the matrix above. In such case, the signature matrix (denoted as S₁) would is given by the following exemplary matrix:

$${S}_{1} = [ \begin{matrix}1 & 1 & 1 & 1 & 1 & 1 \\ 0 & 0 & 1 & 1 & 0 & 0 \\ 1 & 1 & 0 & 0 & 0 & 0 \\ 0 & 0 & 0 & 0 & 1 & 1\end{matrix} ]$$

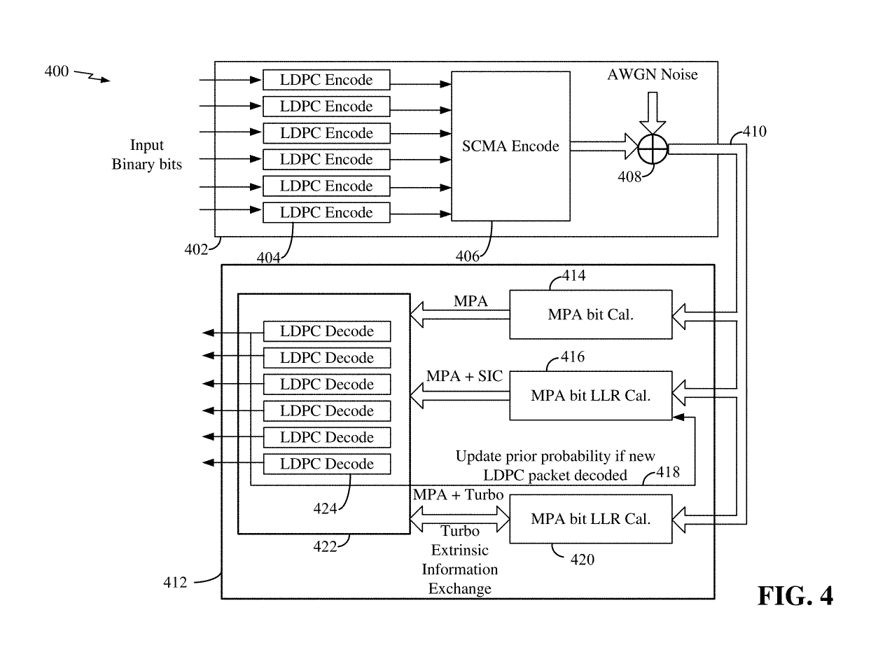

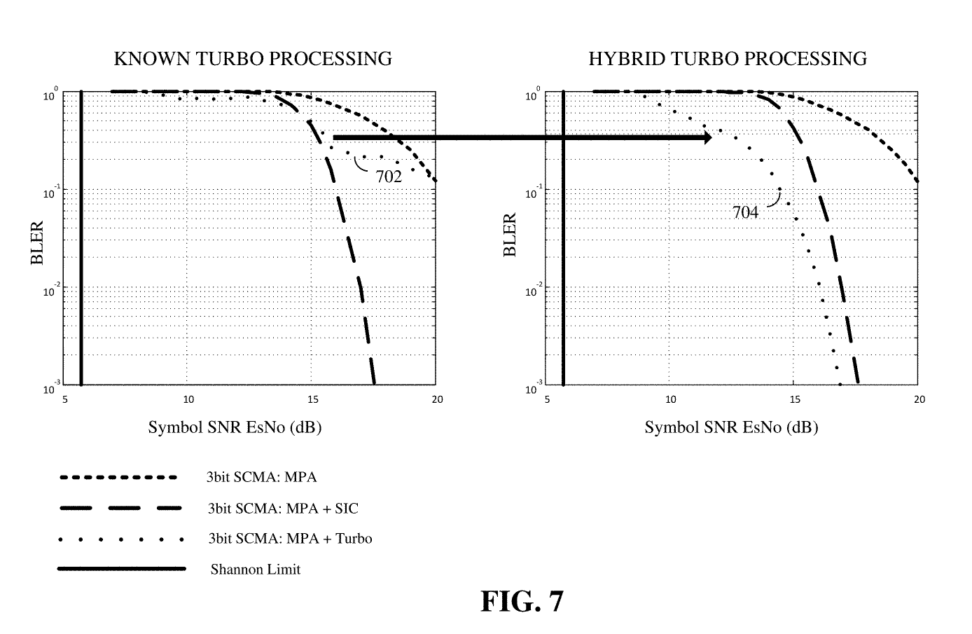

FIG. 4 illustrates a block diagram 400 showing an exemplary modeled system of a transmitter and receiver in which the presently disclosed methods and apparatus for modifying decoding may be employed. On the transmitter side, FIG. 4 illustrates a transmitter 402 that may utilize encoding with forward error correction using low-density parity check (LDPC) codes, as one example, although not limited to such. In particular, a number of LDPC encoder blocks 404 are used. In one example, the rate of the LDPC encoder block 404 may be set at R=1/2, although various rates may employed. The encoded bits are then SCMA modulated and spread with an SCMA encoder 406, although the transmitter 402 is not limited to such encoding. As part of the modeling of noise that may normally be present in a wireless interface, the insertion of added white Gaussian noise (AWGN) is also shown by addition block 408 adding the AWGN to the output of SCMA encoder 406 in FIG. 4. It is noted that the insertion of AWGN is illustrated here to merely show how an exemplary modelling set up estimates a real world situation when trying to determine realistic testing results (See e.g., FIG. 7, which will be discussed later herein). Those skilled in the art will appreciate that an implemented transmitter would not utilize added AWGN.

On the receiver side of the modelled wireless interface 410, a receiver 412 includes at least three types of receiver configurations in the example of FIG. 4: (1) a low complexity message passing algorithm (MPA) receiver decoder 414 that computes bit log likelihood ratios (LLRs) (converted from symbol LLR) assuming no a priori information; (2) an MPA based decoder 416 with jointed serial interference cancellation (SIC) where initially the MPA has no symbol a priori information, but once a packet is decoded after LDPC decoding, then a priori information is fully known (See iterative feedback 418) and the MPA is rerun to update the LLR (and also where iteration stops when no new packet is decoded); and (3) a decoder 420 utilizing MPA with turbo decoding where turbo extrinsic information exchange occurs between the MPA (i.e., SCMA MPA) decoder 420 and an LDPC decoder 422 with LDPC decode elements 424 corresponding to the LDPC encode elements 404 in transmitter 402. The LDPC decoder 422 includes extrinsic information exchange (e.g., feedback) for at least the Turbo decoder 420. It is noted that the example of FIG. 4 is merely exemplary, and that the encoding and decoding schemes need not necessarily be limited to SCMA MPA and LDPC encoding and decoding for implemented the disclosed methods and apparatus.

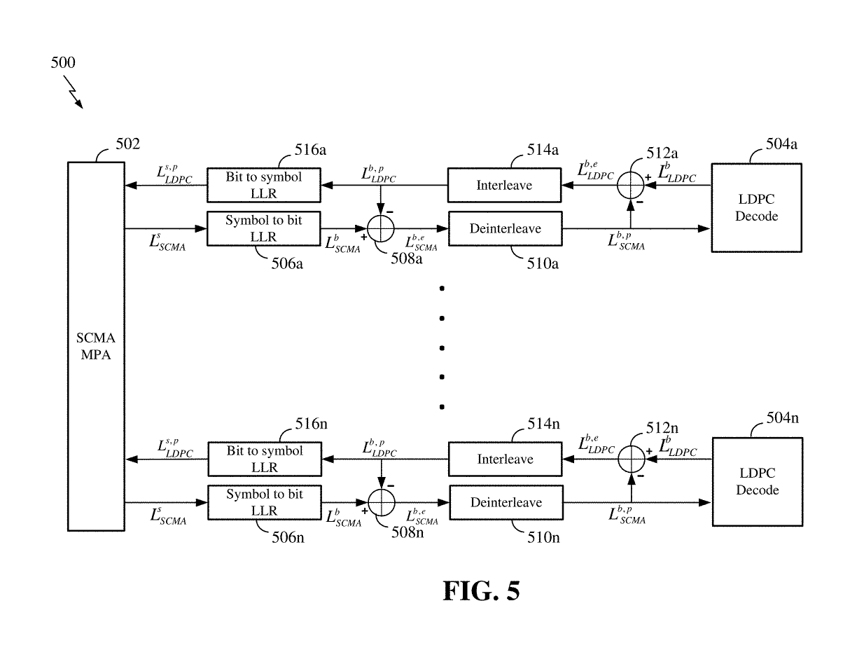

As a more detailed example of a Turbo decoder system with information exchange with an LDPC decoder, such as the exchange between MPA decoder 420 and LDPC decode element 424 in FIG. 4, FIG. 5 illustrates an exemplary block diagram of Turbo decoder system 500 that may be used with SCMA MPA decoding and LDPC decoding. FIG. 5 illustrates a typical turbo decoding arrangement, where turbo decoding is an iterative soft information exchange (i.e., extrinsic information exchange) between two component decoders. As shown in the example of FIG. 5, the system 500 includes an MPA SCMA decoder 502 and LDPC decoders 504a-504n, which correspond to LDPC decode blocks 424 in FIG. 4. The MPA SCMA decoder 502 and an LDPC decoder 504a are coupled with a forward path including a symbol to bit (log likelihood ratio) LLR converter 506a, a summing node 508a, and a deinterleaver 510a. The MPA SCMA decoder 502 and the LDPC decoder 504a are also coupled with a feedback path including a summing node 512a, an interleaver 514a, and a bit to symbol (log likelihood ratio) LLR converter 516a. The values L_{LDPC}^{b}, L_{LDPC}^{b,e}, L_{LDPC}^{b,p}, L_{LDPC}^{s,p} illustrated in FIG. 5 respectively represent an a posteriori bit LLR, a bit extrinsic LLR, an a priori bit LLR, and an a priori symbol LLR from the LDPC decoder 504. Additionally, values L_{SCMA}^{s}, L_{SCMA}^{b}, L_{SCMA}^{b,e}, L_{SCMA}^{b,p} respectively represent an a posteriori symbol LLR, an a posteriori bit LLR, a bit extrinsic LLR, and an a priori bit LLR from the SCMA decoder 502.

In operation, the system 500 is configured to iteratively exchange information between the SCMA MPA decoder 502 and the LDPC decoder 504a in order to engender better decoding performance. The system 500 first starts with initializing value the a priori bit LLR value L_{LDPC}^{b,p} to zero (0). Next during at least one iteration, the a priori bit LLR is converted to the a priori symbol LLR (i.e., L_{LDPC}^{b,p}→L_{LDPC}^{s,p}) with the bit to symbol LLR converter 516a. At the SCMA MPA decoder 502, the a priori symbol LLR input to SCMA MPA decoder engenders the output of the a posteriori symbol LLR (i.e., L_{LDPC}^{s,p}→L_{SCMA}^{s}). The a posteriori symbol LLR is converted to a bit LLR with symbol to bit LLR converter 506a (i.e., L_{SCMA}^{s}→L_{SCMA}^{b}). The SCMA decoder extrinsic information L_{SCMA}^{b,e} is computed with summing node 508a, where L_{SCMA}^{b}→L_{SCMA}^{b,e} through the subtraction of the a priori bit LLR value L_{LDPC}^{b,p}.

The SCMA decoder extrinsic information L_{SCMA}^{b,e} is deinterleaved to determine the a priori bit LLR (i.e., L_{SCMA}^{b,e}→L_{SCMA}^{b,p}), which is communicated to the LDPC decoder 504a. In turn, based on the a priori bit LLR L_{SCMA}^{b,p}, the LDPC decoder 504a outputs the a posteriori bit LLR (i.e., L_{SCMA}^{b,p}→L_{LDPC}^{b}). LDPC decoder extrinsic information LLD L_{LDPC}^{b,e} is then computed with the summing node 512a by subtracting the a priori bit LLR L_{SCMA}^{b,p}. Further, the a priori bit LLR is interleaved to derive the a priori bit LLR L_{LDPC}^{b,p}.

Expressed in simpler terms, the SCMA MPA decoder 502 outputs information to the LDPC decoder 504a and, based on the SCMA MPA decoder output, the LDPC decoder 504a, in turn, will update its output and feedback information to the SCMA decoder 502. The SCMA MPA decoder 502 can use the new feedback from LDPC decoder 504a to help provide more accurate output to be fed back to LDPC decoder. Additionally, the exchange of information is iterative, wherein information is exchanged back and forth between the two decoders multiple times for decoding of a symbol.

According to an aspect, the presently disclosed methods and apparatus include a hybrid or modified decoder that affords stabilization and improvement of decoder processing, such as the Turbo processing of FIG. 5 as one example. In particular, the present methods and apparatus dynamically identify the occurrence of the numerical problems by tracking a packet decoding success rate of a decoder. Based on the numerical problem occurrence, the hybrid or modified operation effects switching between hard and soft information exchange. Still further, based on the numerical problem occurrence, soft information exchange processing (e.g., turbo processing) may be halted or ended to prevent further performance deterioration.

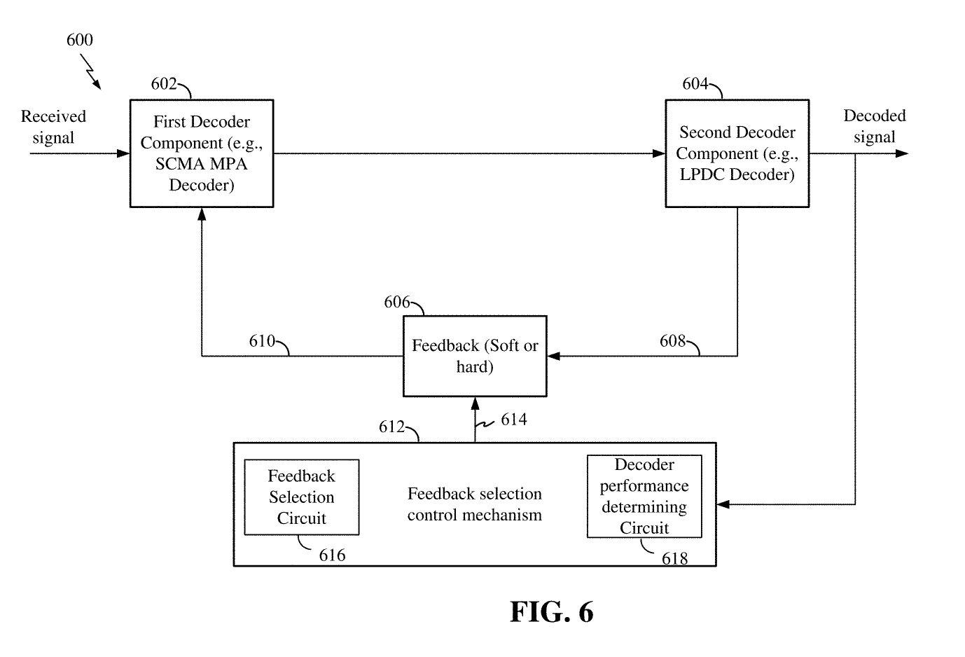

FIG. 6 illustrates an example of a decoder system 600 that may be utilized with transmitter/receiver arrangement illustrated in FIG. 4 and the Turbo decoding system illustrated in FIG. 5, for example. Nonetheless, the system illustrated in FIG. 6 is not limited to use with only LDPC and SCMA encoding/decoding, and may be applied to other encoding/decoding schemes. Additionally, illustrated system 600 may be considered as a generalized arrangement that encompasses the system of FIG. 5, and applies further to other arrangements as well.

In each decoder block (e.g., the decoder block consisting of SCMA MPA 502 and LDPC decoder 504a), the decode output can be soft information (e.g., the LLR of each bit) or hard information (e.g., a bit value of zero (0) or one (1)). The soft information, such as an LLR, is essentially the output of a probability metric of the bit value, whereas the hard information is the output of a final decision whether the bit to be decoded is 1 or 0. The decoder system 600 illustrates an example of a modified or hybrid decoder scheme that provides selective switching between the use of the soft information output (e.g., the LLR of each bit) of the decoder block and the hard information (e.g., a bit value of zero (0) or one (1)) also available at each decoder block. The selective switching is decided by determining whether the output of the decoding process experiences deterioration or reduction in the decoding performance (i.e., a numerical problem occurrence or reduction of LLR quality). The determination of deterioration or reduction of the LLR quality may be based on the decode success rate in one example. In another example, detection of the LLR quality may be accomplished through evaluation of the post decoding SNR in the receiver.

As illustrated in FIG. 6, the system 600 includes a first decoder component block 602, which may be an SCMA MPA decoder in an example, and a second decoder component block 604, which may be an LDPC decoder in an example. Information from the first decoder component block 602 is passed to the second decoder component block 604. Additionally, system 600 includes a feedback path conceptualized with the illustrated feedback block 606 and couplings 608, 610. It is noted that the while the feedback loop is shown as a singularity in FIG. 6, the hard and soft information exchange feedback may be two respective couplings. Furthermore, the feedback system (e.g., 606, 608, 610) is configured to allow selective switching between hard information exchange and soft information exchange. This switching between soft and hard information feedback may be accomplished by physical switching of information couplings or through modifying the operation of the feedback components. According to other aspects, the switching is implemented in firmware, software, and/or hardware controlled by software or firmware. In an exemplary implementation, the feedback obtains the hard or soft information (i.e., the soft LLR or the hard decoding result) from different memory pools.

Furthermore, the system 600 includes a feedback selection control mechanism or means 612 for determining the performance output of the decoding system 600, and, in particular, to determine if a reduction or degradation of the output decoding performance is occurring. This determination, according to one example, may be based on tracking the packet decode success rate. In an aspect, this tracking may include determining if a previously decoded packet or layer is decoded incorrectly a current iteration through a pass-parity check or cyclic redundancy check (CRC). In further aspects, performance degradation may alternatively be determined by tracking if a decrease in the output signal to interference noise ratio (SINR) of the decoder output is occurring. In still a further aspect, performance degradation could be determined by tracking if the decoder output decision distance to the valid codewords in increasing. Moreover, other metrics that may be used for triggering a switch from soft to hard information in a decoder could include consideration of the signal to noise ratio (SNR) operation region, or determination of the occurrence of numerical saturation in a fixed point implementation.

The mechanism also then provides for causing the selection between either passing soft information or passing hard information between the first and second decoder components 602 and 604. This mechanism is illustrated conceptually with feedback selection control mechanism 612, which is shown receiving an output of the decoder system 600 for determination of the performance output of the system 600, and outputting a signal or message 610 to switch the feedback system between soft and hard information. According to an aspect, the feedback selection control mechanism 612 may include circuitry or components for monitoring the decoder performance, as well as for selecting between hard or soft feedback. This circuitry is shown conceptually with feedback selection circuit 616 and decoder performance determining circuit 618 within mechanism 612 according to one example.

It is noted that the block diagram of FIG. 6 is merely conceptual and does not necessarily illustrate specific couplings or all mechanisms to achieve the selective switching, but nonetheless would be known to those skilled in the art. For example, the control of the switching of the feedback between soft or hard information may be accomplished by signaling each of the first and second decoder component blocks 602 and 604. In another aspect, the feedback selection control functionality may be implemented within the first and second decoder components 602 and 604, rather than with a discrete control such as block 608. Additionally, in other aspects there may be two alternate couplings or paths for the feedback information dependent on whether soft or hard information is being communicated between the decoder component blocks 602 and 604. For example, the soft information feedback may be embodied with the configuration illustrated in FIG. 5, whereas the hard information feedback is accomplished with separate couplings between the first and second decoder component blocks 602 and 604.

According to another aspect, the system 600 may operate such that soft information is passed in the communication between the decoder component blocks 602 and 604 as a default mode of operation. Upon detection of the reduction or degradation of the decoder system 600 output, the system 600 switches to passing hard information. The soft information feedback mechanism would then be reset (e.g., initialized to start values for LLRs, and so forth). Although the switch to communicating hard information might eliminate the need for any further decoding of a particular bit, it is noted that the system 600 may be configured to switch back and forth between the communication of soft information and hard information in some aspects.

The system 600 provides a modified or hybrid model for a decoder or decoding system that stabilizes decoder processing and improve processing performance. In an aspect, the system employs Turbo processing, and the hybrid model improves the performance of the Turbo processing. As an example of the improvement afforded by the disclosed hybrid model, FIG. 7, illustrates a comparison of plots of the block error rate (BLER) with respect to the symbol signal to noise ratio (SNR) per bit (i.e., Es/No (Energy per Symbol divided by noise power spectral density)) for a conventional decoder using Turbo decoding and the presently disclosed hybrid Turbo decoding that allows selective switching between soft and hard feedback information based on a simulation of the two systems. In the example of FIG. 7, the three different decoding systems illustrated in FIG. 4 were modeled; namely an MPA decoder, an MPA+SIC decoder, and an MPA+Turbo decoder. As may be seen in the plots, the MPA and MPA+SIC plots are essentially the same as the disclosed hybrid model most effectively provides improvement for Turbo processing. For the MPA+Turbo processing, however, the plot 702 illustrates that the decoding performance in the known turbo processing, which only uses soft information feedback, can degrade or reduce due to various factors as discussed before. On the other hand, plot 704 illustrates that the use of the system of FIG. 6, for example, results is better stabilization of the decoding process for turbo processing.

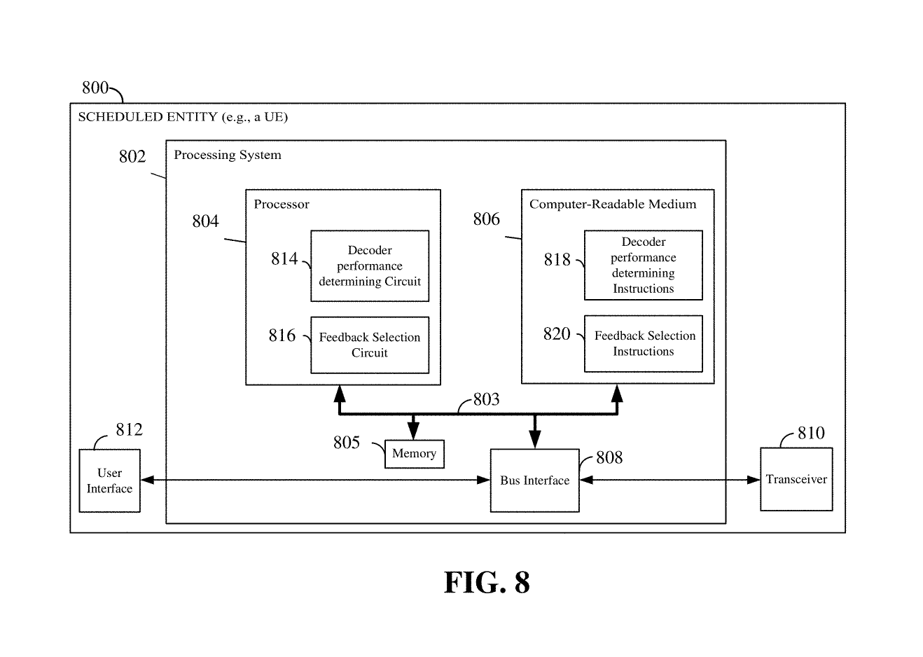

FIG. 8 is a simplified block diagram illustrating an example of a hardware implementation for a scheduled entity 800 employing a processing system 802. In an aspect, the entity 800 may be a user equipment (UE) or a base station, such as illustrated in FIG. 1 or any entity capable of receiving data in at least one of a UL or DL direction.

The entity 800 may be implemented with a processing system 802 that includes one or more processors 804. Examples of processors 804 include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. In various examples, the scheduled entity 800 may be configured to perform any one or more of the functions described herein. That is, the processor 804, as utilized in entity 800, may be used to implement any one or more of the processes described herein for decoding including a process of selectively switching a decoder feedback component to pass soft or hard information dependent on the quality of the decoding performance.

In this example, the processing system 802 may be implemented with a bus architecture, represented generally by the bus 803. The bus 803 may include any number of interconnecting buses and bridges depending on the specific application of the processing system 802 and the overall design constraints. The bus 803 communicatively couples various circuits including one or more processors (represented generally by the processor 804), a memory 805, and computer-readable media (represented generally by the computer-readable medium 806). The bus 803 may also link various other circuits such as timing sources, peripherals, voltage regulators, and power management circuits, which are well known in the art, and therefore, will not be described any further. A bus interface 808 provides an interface between the bus 803 and a transceiver 810. The transceiver 810 provides a means for communicating with various other apparatus over a transmission medium, and may include at least in part means for transmitting and receiving signals modulated according to various wireless technologies including SCMA. Depending upon the nature of the apparatus, a user interface 812 (e.g., keypad, display, speaker, microphone, joystick) may also be provided.

In some aspects of the disclosure, the processor 804 may include circuitry 814 configured for various functions, including, for example, determining decoder performance of at least one decoder in transceiver 810, for example. In other aspects of the disclosure, the processor may include selection circuitry 816 that selects or provides an indication to the at least one decoder in the transceiver 810 to select a particular feedback scheme; i.e., select between soft or hard information feedback in the decoder. Additionally, circuitry 814 and 816 may communicatively couple with or interface with the transceiver 810 for helping direct at least the decoding of signals through employment of the selective feedback scheme disclosed herein.

The processor 804 is responsible for managing the bus 803 and general processing, including the execution of software stored on the computer-readable medium 806. The software, when executed by the processor 804, causes the processing system 814 to perform the various functions described below for any particular apparatus. The computer-readable medium 806 and the memory 805 may also be used for storing data that is manipulated by the processor 804 when executing software.

One or more processors 804 in the processing system may execute software. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise. The software may reside on a computer-readable medium 806. The computer-readable medium 806 may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium 806 may reside in the processing system 802, external to the processing system 802, or distributed across multiple entries including the processing system 802. The computer-readable medium 806 may be embodied in a computer program product. By way of example, a computer program product may include a computer-readable medium in packaging materials. Those skilled in the art will recognize how best to implement the described functionality presented throughout this disclosure depending on the particular application and the overall design constraints imposed on the overall system.

In one or more examples, the computer-readable storage medium 806 may include decoder performance determining instructions or software 818 configured for various functions, including, for example, determining the decoder performance of a decoder in transceiver 810. In a further aspect, the computer-readable storage medium 806 may include feedback selection instructions or software 820 configured for various functions, including, for example, selection of the feedback scheme to be used by the decoder based on the determination made by instructions 818. In particular, the feedback selection instructions are configured to cause selection of soft information feedback or hard information feedback based on the determined decoder performance.

In one configuration, the apparatus 800 for wireless communication includes means for determining decoding performance occurring in a decoder having first and second decoder components with a feedback component between the first and second decoder components. Additionally, the apparatus 800 may include means for selectively switching between feedback passing soft information between the first and second decoder components with the feedback component and feedback passing hard information between the first and second decoder components based on the determined decoding performance. In one aspect, the aforementioned means may be the processor(s) 804 in which the invention resides and configured to perform the functions recited by the aforementioned means. In another aspect, the aforementioned means may be a circuit or any apparatus configured to perform the functions recited by the aforementioned means.

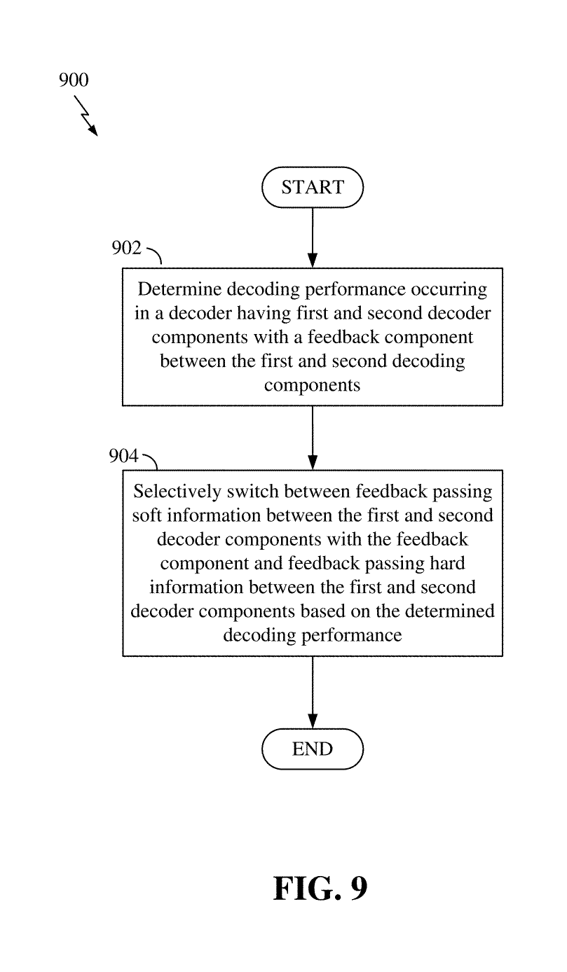

Of course, in the above examples, the circuitry included in the processor 804 is merely provided as an example, and other means for carrying out the described functions may be included within various aspects of the present disclosure, including but not limited to the instructions stored in the computer-readable storage medium 806, or any other suitable apparatus or means described herein, and utilizing, for example, the processes and/or algorithms described herein in relation to FIG. 9 discussed below.

FIG. 9 is a flow chart illustrating an exemplary process or methodology 900 for wireless communication in accordance with aspects of the present disclosure. As described below, some or all illustrated features may be omitted in a particular implementation within the scope of the present disclosure, and some illustrated features may not be required for implementation of all embodiments. In some examples, the process 900 may be carried out by the subordinate or scheduled entity 800 illustrated in FIG. 8. In some examples, the process 900 may be performed by any suitable apparatus or means for carrying out the functions or algorithms described below.

As illustrated, process 900 includes determining decoding performance occurring in a decoder including first and second decoder components having a feedback component between the first and second decoder components as illustrated in block 902. As an example, the processes in block 902 may be effected by various means such as feedback selection control 612, as well as component 618 in control 612 or equivalents thereof in some examples. In other examples, means for effecting the functions of block 912 may be implemented with decoder performance determining circuit 814 in processor 804 illustrated in FIG. 8, or equivalents thereof.

Process 900 further includes selectively switching between feedback passing soft information between the first and second decoder components and feedback passing hard information between the first and second decoder components based on the determined decoding performance as shown at block 904. As an example, the processes in block 904 may be effected by various means such as feedback selection control 612, as well as component 616 in control 612 or equivalents thereof in some examples. In other examples, means for effecting the functions of block 912 may be implemented with feedback selection circuit 816 in processor 804 illustrated in FIG. 8, or equivalents thereof.

Although not shown in FIG. 9, the process 900 may further include that the feedback passing soft information is operable according to Turbo processing, such as the Turbo processing illustrated in FIG. 5, as one example. Additionally the determination of the decoding performance occurring in the decoder may include tracking a packet decoding success rate of the decoder, or other suitable metrics to determine if the decoder performance is degraded or reduced. In addition, as discussed before, switching of the operation of the decoder from a feedback passing soft information between the first and second decoder components to a feedback passing hard information may be triggered when the determined decoding performance is reduced. As will be appreciated from the disclosure above, the feedback in process 900 is iterative when passing information back and forth between the first and second decoder components, and this iterative process continues for each decoded bit. Additionally, it will be appreciated by those skilled in the art then that the determination of decoding performance of the decoder, upon which the switching decision is made, may be performed during each iteration of the feedback.

In a further aspect, the first decoder component is a sparse code multiple access (SCMA) decoder and the second decoder component is a low-density parity-check (LDPC) decoder, such as may be envisioned by the system of FIG. 5. Furthermore, the soft information in process 900 may include at least a Log Likelihood Ratio (LLR) of at least one bit to be decoded, and the hard information in process 900 may include a binary bit decision of either zero or one, as examples. Furthermore, it is noted that the switching between feedback using soft or hard information is not limited to once per bit processed, and that switching between hard and soft information feedback may be envisioned as being capable of being performed multiple times over the decoding process of a particular bit. In addition, process 900 may include resetting the soft information feedback system (e.g., initialization of the Turbo decoding system as discussed in connection with FIG. 5) after the decoder has been switched from soft information feedback to hard information feedback.

In yet another aspect, the methodology 900 may be further configured such that soft information exchange processing (e.g., turbo processing) may be halted, stopped, or ended to prevent further performance deterioration based on the detected numerical problem occurrence. For example, in the known processing system illustrated in FIG. 7, it may be seen from plot 702 that decoding performance of the system when using SCMA+MPA turbo decoding starts to deteriorate because of numerical problem occurrence around the point where the symbol SNR EsNo is about 15 dB. Method 900, as well as system 600 implementing the disclosed hybrid decoding, may be configured such that after a threshold SNR EsNo is reached without a decrease in the BLER, the method (or feedback control mechanism 612) stops turbo processing or soft information exchange altogether and selects only hard information feedback. As discussed before, a few ways to detect the condition for stopping or halting soft feedback include (1) the deterioration of the decoding performance based on a CRC check or a channel coding parity matrix check, (2) the deterioration of the LLR quality, and/or (3) the deterioration of the post decoding signal to noise ratio (SNR).

Several aspects of a wireless communication network have been presented with reference to an exemplary implementation. As those skilled in the art will readily appreciate, various aspects described throughout this disclosure may be extended to other telecommunication systems, network architectures and communication standards.

By way of example, various aspects may be implemented within other systems defined by 3GPP, such as Long-Term Evolution (LTE), the Evolved Packet System (EPS), the Universal Mobile Telecommunication System (UMTS), and/or the Global System for Mobile (GSM). Various aspects may also be extended to systems defined by the 3rd Generation Partnership Project 2 (3GPP2), such as CDMA2000 and/or Evolution-Data Optimized (EV-DO). Other examples may be implemented within systems employing IEEE 802.11 (Wi-Fi), IEEE 802.16 (WiMAX), IEEE 802.20, Ultra-Wideband (UWB), Bluetooth, and/or other suitable systems. The actual telecommunication standard, network architecture, and/or communication standard employed will depend on the specific application and the overall design constraints imposed on the system.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another, even if they do not directly physically touch each other. For instance, a first object may be coupled to a second object even though the first object is never directly physically in contact with the second object. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in FIGS. 1-9 may be rearranged and/or combined into a single component, step, feature or function or embodied in several components, steps, or functions. Additional elements, components, steps, and/or functions may also be added without departing from novel features disclosed herein. The apparatus, devices, and/or components illustrated in this disclosure may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b, and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

What is claimed is:

1. A method of wireless communication, comprising:
determining decoding performance occurring in a decoder having first and second decoder components with a feedback component between the first and second decoder components; and
selectively switching between feedback passing soft information between the first and second decoder components with the feedback component and feedback passing hard information between the first and second decoder components based on the determined decoding performance.

2. The method of claim 1, wherein the feedback component passing soft information is operable according to Turbo processing.

3. The method of claim 1, wherein determining the decoding performance occurring in the decoder includes determining a packet decoding success rate of the decoder.

4. The method of claim 1, wherein the decoder is switched from feedback passing soft information between the first and second decoder components to feedback passing hard information between the first and second decoder components when the determined decoding performance is reduced.

5. The method of claim 1, wherein the feedback is iterative, and the determination of decoding performance of the decoder is performed during each iteration of the feedback.

6. The method of claim 1, wherein the first decoder component is a sparse code multiple access (SCMA) decoder and the second decoder component is a low-density parity-check (LDPC) decoder.

7. The method of claim 1, wherein the soft information comprises at least a Log Likelihood Ratio (LLR) of at least one bit to be decoded, and the hard information comprises a binary bit decision of either zero or one.

8. An apparatus for wireless communication, comprising:
at least one processor;
a transceiver communicatively coupled to the at least one processor and including at least one decoder; and
a memory communicatively coupled to the at least one processor,
wherein the at least one processor is configured to:
determine decoding performance occurring in the decoder that includes first and second decoder components and a feedback component between the first and second decoder components; and
selectively switch between feedback passing soft information between the first and second decoder components with the feedback component and feedback passing hard information between the first and second decoder components based on the determined decoding performance

9. The apparatus of claim 8, wherein the feedback passing soft information is operable according to Turbo processing.

10. The apparatus of claim 8, wherein determining the decoding performance occurring in the decoder includes determining a packet decoding success rate of the decoder.

11. The apparatus of claim 8, wherein the decoder is switched from feedback passing soft information between the first and second decoder components to feedback passing hard information between the first and second decoder components when the determined decoding performance is reduced.

12. The apparatus of claim 8, wherein the feedback is iterative, and the determination of decoding performance of the decoder is performed during each iteration of the feedback.

13. The apparatus of claim 8, wherein the first decoder component is a sparse code multiple access (SCMA) decoder and the second decoder component is a low-density parity-check (LDPC) decoder.

14. The apparatus of claim 8, wherein the soft information comprises at least a Log Likelihood Ratio (LLR) of at least one bit to be decoded, and the hard information comprises a binary bit decision of either zero or one.

15. A non-transitory computer-readable medium storing computer-executable code, comprising code for causing a computer to:
determine decoding performance occurring in a decoder having first and second decoder components with a feedback component between the first and second decoder components; and
selectively switch between feedback passing soft information between the first and second decoder components with the feedback component and feedback passing hard information between the first and second decoder components based on the determined decoding performance.

16. The non-transitory computer-readable medium of claim 15, wherein the feedback component passing soft information is operable according to Turbo processing.

17. The non-transitory computer-readable medium of claim 15, wherein determining the decoding performance occurring in the decoder includes determining a packet decoding success rate of the decoder.

18. The non-transitory computer-readable medium of claim 15, wherein the decoder is switched from feedback passing soft information between the first and second decoder components to feedback passing hard information between the first and second decoder components when the determined decoding performance is reduced.

19. The non-transitory computer-readable medium of claim 15, wherein the feedback is iterative, and the determination of decoding performance of the decoder is performed during each iteration of the feedback.

20. The non-transitory computer-readable medium of claim 15, wherein the soft information comprises at least a Log Likelihood Ratio (LLR) of at least one bit to be decoded, and the hard information comprises a binary bit decision of either zero or one.
